(19) United States
(12) Patent Application Publication
(10) Pub. No.: US 2005/0179042 A1
(43) Pub. Date: Aug. 18, 2005

(54) Monolithic integration and enhanced light extraction in gallium nitride-based light-emitting devices

(75) Inventors: Bo Yang, Providence, RI (US); Tchang-hun Oh, Sharon, MA (US); Brenda Dingle, Mansfield, MA (US); William T. Roberts, North Attleboro, MA (US); Ilya Libenzon, Wilmington, MA (US); Hong K. Choi, Sharon, MA (US); John C. C. Fan, Brookline, MA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Kopin Corporation, Taunton, MA (US)

(21) Appl. No.: 11/057,695

(22) Filed: Feb. 14, 2005

Related U.S. Application Data
(60) Provisional application No. 60/544,577, filed on Feb. 13, 2004.
(60) Provisional application No. 60/553,718, filed on Mar. 15, 2004.
(60) Provisional application No. 60/553,717, filed on Mar. 15, 2004.

(51) Int. Cl. H01L 27/15

(52) U.S. Cl. 257/84

(57) ABSTRACT

An integrated light-emitting device includes multiple p-n diodes integrated monolithically on an insulating substrate. The p-n diodes are of monolithic semiconductor materials over the single substrate. The p-n diodes can be all light-emitting diodes or a combination of light-emitting and ESD-protection diodes. The p-n diodes may have at least one beveled sidewall to enhance light extraction out of the light-emitting diodes. A method for producing such integrated light-emitting device and a method for producing such p-n diode that includes at least one beveled sidewall are also disclosed.

### RELATED APPLICATIONS

This application claims the benefit of U.S. Provisional Application No. 60/544,577, filed on Feb. 13, 2004. This application also claims the benefit of U.S. Provisional Application Nos. 60/553,718 and 60/553,717, both of which were filed on Mar. 15, 2004. The entire teachings of the above applications are incorporated herein by reference.

### BACKGROUND OF THE INVENTION

In general, gallium nitride (GaN)-based light emitting devices are based on a p-n diode structure including n-type and p-type GaN-based semiconductor layers stacked on top of a substrate through a process of epitaxial or domain epitaxial growth. A GaN-based light-emitting device with a traditional single p-n diode structure has been widely utilized as an efficient light source for realizing such colors as blue, green, and white. However, as GaN-based light-emitting devices become utilized in diverse applications, it becomes challenging for a traditional single p-n diode structure to meet the requirements of these diverse applications.

One of the requirements is protection of light-emitting devices against electro-static discharge. Electro-static discharge (ESD) is the buildup of electrical energy and its sudden release. Typically, in the light-emitting devices, ESD is caused by the imbalance of electrical charges at interfaces between the light-emitting devices and other external environments. This ESD can cause a catastrophic device failure by an electrical overstress, causing a larger amount of current to flow through the device than it can tolerate. In order to minimize the failure of devices due to ESD events, a proper protection from an ESD event up to at least a certain energy level is required. A zener diode made of silicon is widely used for ESD protection in various electronic devices. A structure connecting a light-emitting diode with a silicon zener diode has been proven effective, resulting in superb ESD protection in many industry practices. Using two discrete components to provide ESD protection, however, requires an additional bonding process during the device packaging between the zener and light-emitting diodes. Conventionally, the additional bonding, e.g., between the light-emitting and zener diodes, has been achieved either by a wire-bonding connecting the electrodes of the two p-n diodes with metal wires or by a bump-bonding where the connection is made by metal bumps. However, these existing approaches increase complexity and cost of packaging processes.

Another requirement is to increase overall light output from a single light-emitting device package. To achieve this goal, one method may be to use multiple light-emitting devices in series. Another method may be to enhance light extraction out of individual light-emitting devices.

One example of the first approach in the art is to connect multiple discrete light-emitting devices in series. However, as discussed above, connecting discrete light-emitting devices by a wire-bonding process increases complexity and cost of packaging processes.

With respect to the second approach, it is challenging to increase light extraction out of a light-emitting device due to intrinsic physical properties of semiconductor materials. In general, GaN-based light-emitting devices are composed of multiple semiconductor layers grown on top of a substrate. The semiconductor layers of light-emitting devices form interfaces with surrounding materials, including the substrate, air, and the encapsulating epoxy typically used in packaging. Due to large differences in the indices of refraction between the GaN-based semiconductor layers and the surrounding materials, a majority of the light generated within the device is trapped within the semiconductor layers, being sandwiched between the substrate and the encapsulating epoxy or surrounding air. This phenomenon is described as total internal reflection. Due to this phenomenon, it is very difficult to extract light from the device effectively. Typically, efficiency of a traditional GaN-based light-emitting device is less than 10%.

### SUMMARY OF THE INVENTION

An integrated light-emitting device of the present invention includes multiple p-n diodes, either all light-emitting diodes or light emitting diode(s) in combination with ESD-protection diode(s), integrated monolithically on a single substrate.

One aspect of the present invention includes an integrated device comprising an insulating substrate and multiple p-n diodes of monolithic semiconductor materials over the insulating substrate. Preferably, the monolithic semiconductor materials are GaN-based semiconductor materials.

In one embodiment, the integrated device of the invention includes at least one light-emitting device of monolithic semiconductor materials over the insulating substrate. Each light-emitting device includes a light-emitting diode and an electro-static discharge protection diode, which are formed from the monolithic semiconductor materials. The light-emitting diode and electro-static discharge protection diode are interconnected with each other through electrodes of opposite polarities of the light-emitting and electro-static discharge protection diodes.

In another embodiment, the integrated device of the invention includes a plurality of light-emitting devices of monolithic semiconductor materials over the insulating substrate. Each of the light-emitting devices includes a light-emitting diode. The light-emitting devices are connected in series through electrodes of opposite polarities of the light-emitting diode component of the light-emitting devices.

The present invention also includes a method of producing an integrated device. The method comprises depositing a set of semiconductor layers over an insulating substrate to produce a monolithic p-n junction structure. From the monolithic p-n junction structure, multiple electrically-isolated p-n diode structures are formed. Electrodes on the p-n diodes are formed on the p-n diode structures to produce p-n diodes. The method also includes interconnecting electrodes of opposite polarities of the p-n diodes.

In one embodiment, the method of the invention produces at least one light-emitting device that includes a light-emitting diode and an ESD-protection diode. The light-emitting and electro-static discharge protection diodes of the light-emitting device are interconnected with each other through electrodes of opposite polarities of the light-emitting and electro-static discharge protection diodes.

In another embodiment, the method of the invention produces a plurality of light-emitting devices that includes a light-emitting diode. The light-emitting devices are connected in series through electrodes of opposite polarities of each of the light-emitting diodes.

Yet another aspect of the present invention includes a light-emitting device comprising a substrate and a light emitting diode over the substrate, where at least one sidewall of the light-emitting diode is beveled.

The present invention also includes a method of producing a light-emitting device having at least one beveled sidewall. The method comprises depositing multiple semiconductor layers over a substrate to produce a p-n junction structure. Using the p-n junction structure, a light-emitting diode structure is formed. A bevel is formed on at least one sidewall of the light-emitting diode structure. A light-emitting diode having at least one beveled sidewall is produced by forming electrodes on the light-emitting diode structure. In some embodiments, beveling at least one sidewall of the light-emitting diode may be performed after the electrodes of the light-emitting diode structure are formed.

With the integrated light-emitting devices of the invention, multiple p-n diodes, either all light-emitting diodes or light-emitting diode(s) in combination with ESD protection didoe(s), are monolithically integrated on a single insulating substrate. The present invention, thus, provides much simpler and more reliable solution than the use of multiple discrete p-n diodes connected by wire-bonding or bump-bonding. Also, the present invention is advantageous over the conventional integration of discrete p-n diodes by wire-bonding or bump-bonding, because multiple p-n diodes are integrated monolithically before packaging, reducing the total number of terminals connected in the package.

In addition, by beveling at least one sidewall of light-emitting device, enhanced light extraction can be achieved. In particular, the integrated device of one embodiment of the invention, where multiple light-emitting devices that includes a light-emitting diode and an ESD protection diode, are monolithically integrated in series on a single substrate can incorporate the beveled sidewall(s). With such a device, efficient protection against ESD and enhanced overall light output can be achieved not only due to enhanced light extraction from individual light-emitting diodes but also due to multiplied light output by the number of total light-emitting diodes. Also, with the method of the present invention, beveling the sidewall(s) of light-emitting diode(s) can be performed while forming electrically-isolated p-n diodes (e.g., light-emitting diode(s) and ESD protection diode(s)) or p-n diode structures. That is, while isolating p-n diodes or p-n diode structures electrically from each other, beveling the sidewall(s) of light-emitting diode(s) can be made simultaneously, reducing processing steps.

### BRIEF DESCRIPTION OF THE DRAWINGS

FIG. 1 is a schematic cross-section of an integrated light-emitting device of the invention that includes two p-n diodes on the same substrate isolated from each other by eliminating conductive semiconductor layers, where diode symbols are drawn for the illustration only.

FIG. 2 is a schematic cross-section of an integrated light-emitting device of the invention that includes two p-n diodes where two electrodes from each diode are connected after device isolation.

FIG. 3 is a symbolic schematic showing the configuration of a light-emitting diode (LED) connected to the ESD-protection diode through the terminals of different polarities.

FIG. 4 is a three-dimensional schematic of an integrated light-emitting device of the invention, where a light-emitting diode is monolithically integrated with an ESD-protection diode.

FIG. 5 is a schematic top view of an integrated light-emitting device of the invention, where a light-emitting diode is monolithically integrated with a relatively small-sized ESD-protection diode.

FIG. 6A is a schematic top view of an integrated light-emitting device of the invention, where an array of four light-emitting diodes are monolithically integrated in series over a common substrate.

FIG. 6B is a schematic cross-section of the circled area in FIG. 6A, showing the interconnection between two adjacent diodes.

FIG. 7A is a schematic top view of an integrated light-emitting device of the invention, where an array of four light-emitting devices are monolithically integrated in series over a common substrate.

FIG. 7B is a schematic top view of the dotted square box area of FIG. 7A, showing the interconnection between two adjacent light-emitting diode and ESD-protection diodes.

FIG. 7C is a schematic cross-section of the circled area in FIG. 7A, showing the interconnection between two adjacent light-emitting diodes.

FIG. 8 is a schematic cross-section of a light-emitting diode of the invention, where the sidewalls of the semiconductor layers were etched with a bevel.

FIG. 9 is an optical microscope image of a light-emitting diode of the invention, which is fabricated with beveled sidewalls created with undulated edge pattern.

FIG. 10 is a cross-sectional scanning electron microscope (SEM) image, showing the light-emitting diode of one embodiment of the invention where the sidewalls of the semiconductor layers are etched with a bevel.

FIG. 11 is a graph showing improvement in light output in the light-emitting diode of one embodiment of the invention, having beveled sidewalls.

### DETAILED DESCRIPTION OF THE INVENTION

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

In general, a light-emitting device contains multiple semiconductor layers grown epitaxially on a substrate, such as sapphire. Alternatively, the semiconductor layers can be grown domain-epitaxially as described in U.S. 2004/0072381 A1, the entire teachings of which are incorporated herein by reference. The growth of semiconductor layers can be achieved by a number of widely-known crystal growth techniques in the art, including metalorganic chemical vapor deposition (MOCVD), molecular beam epitaxy (MBE), and hydride vapor phase epitaxy (HVPE). The epitaxial layers are stacked in such a way to form a vertical p-n junction structure, which is typically achieved by stacking n-type layers and then p-type layers in sequence on top of a substrate. The device described in the present invention can have light emission either from the top surface of the semiconductor layers or from the bottom of the substrate. Preferably, the device of the present invention is a gallium nitride (GaN)-based device.

As used herein, “monolithic semiconductor materials” means that the semiconductor materials are formed as single-crystalline materials on a common substrate. A “monolithic p-n junction structure,” as used herein, means a p-n junction structure that is formed from the monolithic semiconductor materials. Similarly, a “monolithically integrated” device, as used herein, means a device where multiple sub-devices, which are fabricated from the same epitaxially or domain-epitaxially grown semiconductor layers and share the same substrate, are fabricated into a single chip.

To fabricate multiple p-n diodes monolithically on a single substrate, a set of monolithic multiple semiconductor layers are grown on a single substrate by the techniques discussed above to produce a p-n junction structure, and the p-n junction structure is fabricated to produce multiple p-n diode structures, as discussed below. The junction area of each of the p-n diode structures is separately defined on the surfaces of the semiconductor layers. The individual p-n diode structures are then electrically isolated from each other. The electrical isolation of p-n diode structures can be achieved by removing the conductive semiconductor layers between the p-n diode structures. Electrodes can be formed on the electrically-isolated p-n diode structures. Alternatively, electrodes can be formed on the p-n junction structure before producing multiple electrically-isolated diode structures. Electrodes of those isolated diodes are then electrically interconnected. Since the substrate is insulating, there is no electrical path from one device to the other unless an intentional connection is made between the electrodes, i.e., anodes and cathodes, of the p-n diodes.

Removal of selected portions of the conductive semiconductor layers can be achieved by various etching techniques widely used in the semiconductor industry. Typical etching techniques include wet or dry etching techniques. In wet etching, the material is dissolved when immersed in a chemical solution. In dry etching, the material is sputtered or dissolved using reactive ions or a vapor phase etchant. Typically, drying etching involves the plasma chemistry that is used in various types of conventional systems such as RIE (Reactive Ion Etching), ICP (Inductively Coupled Plasma)-RIE (called just ICP in this document), and ECR (Electron Cyclotron Resonance)-RIE.

Once every individual p-n diode is completely isolated from each other, monolithic integration can be achieved by selectively connecting the electrodes of individual diodes, implementing a desired function of the integrated device comprising multiple diodes. Preferably, the connection is via a metal connection. An insulating layer may be deposited between the p-n diode structure of at least one of the p-n diodes and the metal connection.

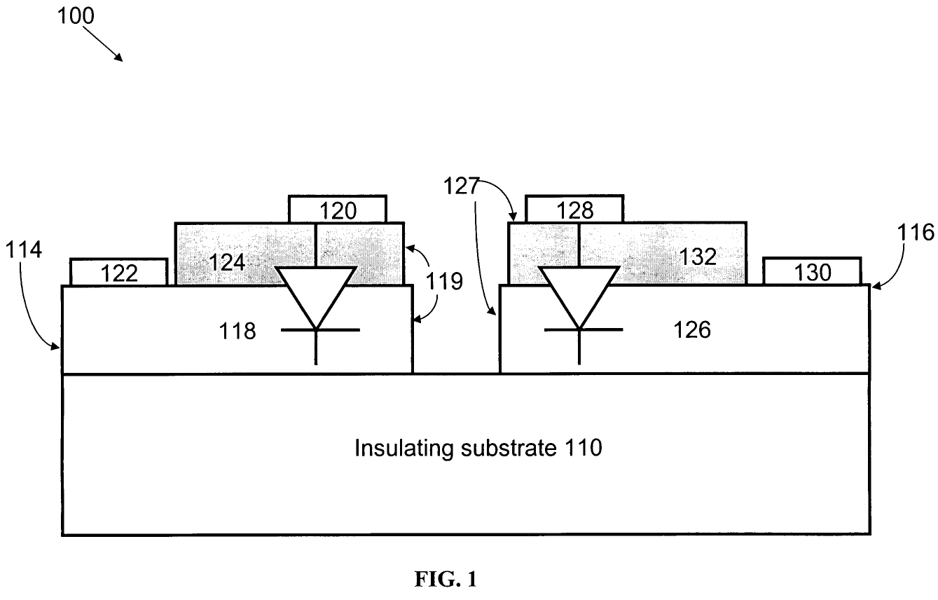

FIG. 1 shows a schematic cross-sectional view of integrated device 100 according to the principles of the present invention. Integrated device 100 includes two p-n diodes over insulating substrate 110, p-n diode 114 and p-n diode 116. P-n diode 114 includes semiconductor layers 118 and 124, together forming p-n diode structure 119, and electrodes 120 and 122. P-n diode 116 includes semiconductor layers 126 and 132, together forming p-n diode structure 127, and electrodes 128 and 130. Semiconductor layers 118 and 124 and semiconductor layers of 126 and 132 are monolithically grown over the single common substrate, insulating substrate 110. Semiconductor layers 118, 124, 126 and 132 are typically grown epitaxially or domain epitaxially, to form p-n diode structures 119 and 127, respectively. In FIG. 1, semiconductor layers 118 and 126 represent n-type semiconductor layers. Alternatively, semiconductor layers 118 and 125 can be a stack of p-type and n-type semiconductor layers where the top layer of the stack is an n-type semiconductor layer. In a preferred embodiment, semiconductor layers 118 and 125 include an active layer, such as a single quantum-well structure or multiple quantum-well structure.

Semiconductor layers 124 and 132 represent p-type semiconductor layers grown on the n-type semiconductor layer. Thus, electrodes 120 and 128 are p-type electrodes (anodes) in electrical contact with p-type semiconductor layers 124 and 132, respectively. Electrodes 122 and 130 are n-type electrodes (cathodes) in electrical contact with n-type semiconductor layer or stack of p-type and n-type semiconductor layers where the top layer of the stack is an n-type semiconductor layer, 118 and 126, respectively.

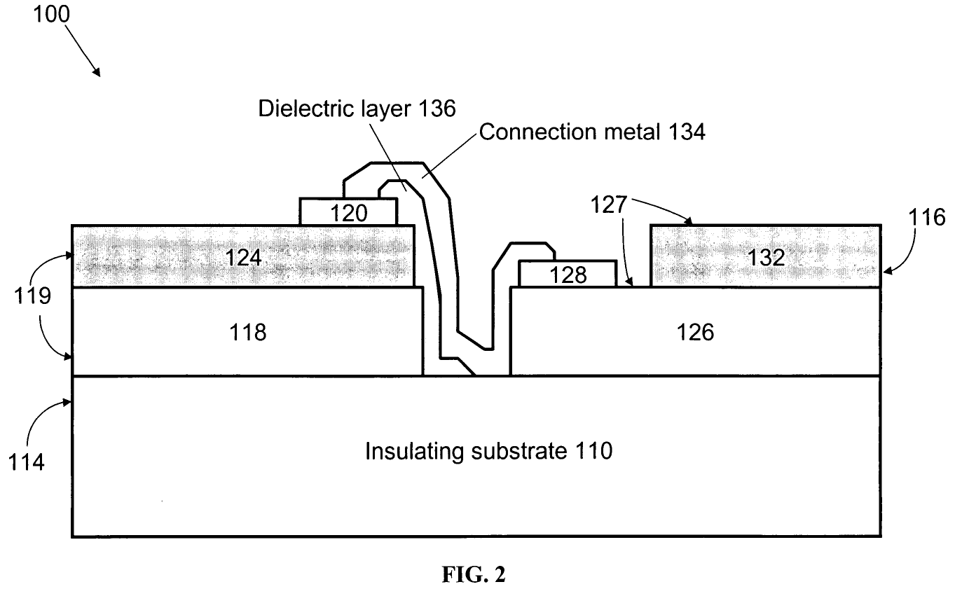

FIG. 2 shows a schematic cross-sectional view of integrated device 100, where electrode 120 (anode) of p-n diode 114 is connected to electrode 128 (cathode) of p-n diode 116 via connection metal 134. Insulating layer 136, such as silicon dioxide or silicon nitride, is deposited between the p-n junction structure of p-n diode 114 and connection metal 134 in order to avoid shorting p-n diode 114 with connection metal 134. In some embodiments, insulating layer 136 can be deposited between the p-n junction structures of both p-n diodes 114 and 116 and connection metal 134.

Unless otherwise specified, it is assumed that integrated device 100 and all later embodiments (integrated devices 200, 300, 400 and 500) thereof, are made according to the principles of the present invention, as described above.

In one embodiment, the integrated device of the invention includes at least one light-emitting device that includes a light-emitting diode and an ESD-protection diode. The light-emitting diode and ESD-protection diode are made from the same monolithic semiconductor materials on a common insulating substrate. With the ESD-protection diode, the integrated device can be protected from high energy ESD events. As discussed above, ESD can potentially cause a catastrophic device failure due to a very large amount of current flowing through the device.

Depending upon the interface conditions of an electrical device, an ESD stimulus can occur in two different polarities, positive or negative, resulting in a forward or a reverse ESD current through the device, respectively. Generally, in a GaN-based light-emitting device, the forward ESD is less likely to cause damage, as the large amount of current is almost uniformly distributed across the whole p-n junction area. In practice, protection of a light-emitting device from negative ESD is more important, as higher energy ESD can be endured in a forward direction.

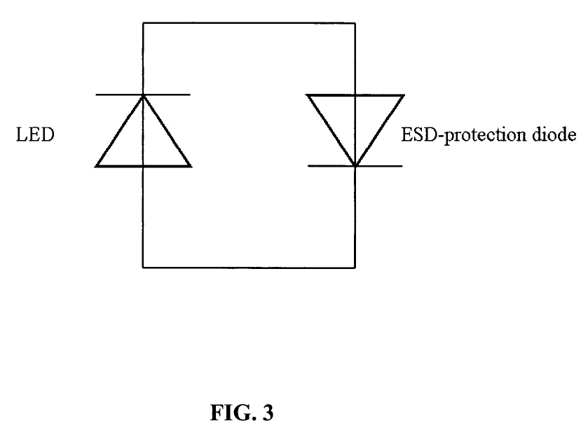

FIG. 3 shows the configuration of the integrated device of one embodiment of the invention. In the event of an ESD of either polarity, positive or negative, one of the two connected diodes is always turned on as a forward-biased diode, discharging ESD-induced charges in a forward current. Therefore, this configuration eliminates the case of a large current flowing in a reverse direction in any ESD event, resulting in an enhanced tolerance to higher energy ESD.

The monolithic integration of the configuration shown in FIG. 3 can be achieved by connecting the electrodes of the opposite polarity between two diodes, i.e., light-emitting and ESD-protection diodes. For example, the anode of the light-emitting diode is connected to the cathode of the ESD-protection diode, and vise versa.

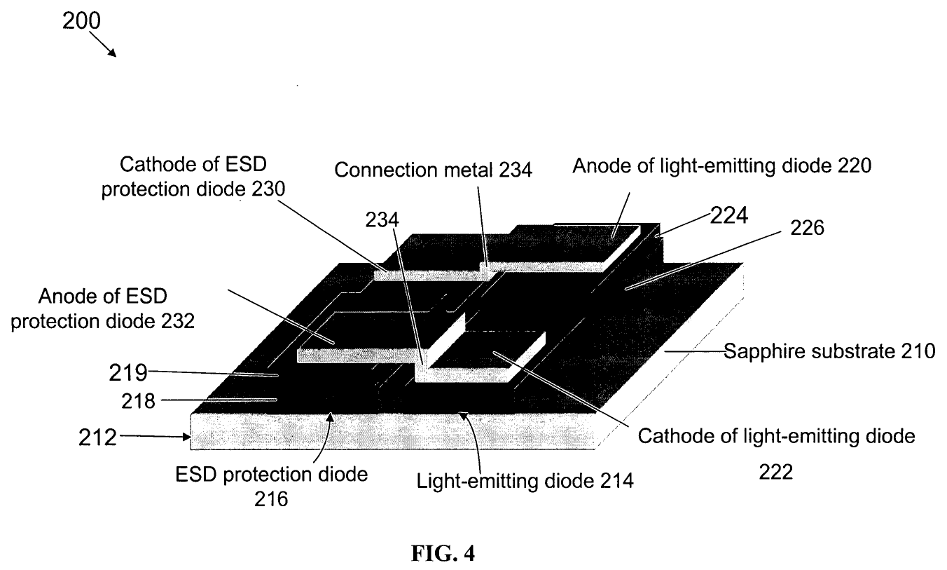

FIG. 4 shows a three-dimensional schematic of integrated device 200 according to the principles of the present invention. Integrated device 200 includes one light-emitting device 212. Light-emitting device 212 includes light-emitting diode 214 and ESD-protection diode 216 over insulating substrate 210, such as sapphire. Light-emitting diode 214 and ESD-protection diode 216 are formed from a common p-n junction structure which in turn produces electrically-isolated p-n diode structures 218 and 219. In integrated device 200, anode 220 of light-emitting diode 214 is connected with cathode 230 of ESD-protection diode 216. Similarly, cathode 222 of light-emitting diode 214 is connected with anode 232 of ESD-protection diode 216. In a preferred embodiment, light-emitting diode 214 and ESD-protection diode 216 are interconnected via connection metal 234. An insulating layer (not shown in FIG. 4), such as insulating layer 136 shown in FIG. 2, can be further deposited under connection metal 234, i.e., between p-n diode structures and connection metal 234. The p-n diode structure of light-emitting diode 214 includes semiconductor layers 224 and 226. The p-n diode structure of ESD-protection diode 216 includes semiconductor layers 218 and 219. FIG. 4, semiconductor layers 224 and 219 represent p-type semiconductor layers. Semiconductor layers 226 and 218 represent n-type semiconductor layers. Alternatively, semiconductor layers 226 and 218 can be a stack of p-type and n-type semiconductor layers where the top layer of the stack is an n-type semiconductor layer.

Depending upon the size of the ESD-protection diode to be integrated with a light-emitting diode, there is a trade-off in the final performance of the light-emitting device between the ESD endurance and other electro-optical parameters, such as forward operating voltage and total light output. ESD endurance becomes better with a larger size protection diode. Bigger protection diodes, however, result in a higher forward operating voltage and a lower light output from the light-emitting device, which are not desirable in typical applications. Therefore, an optimum size has to be chosen to meet the required ESD endurance level, while minimizing the penalty in forward voltage and light output.

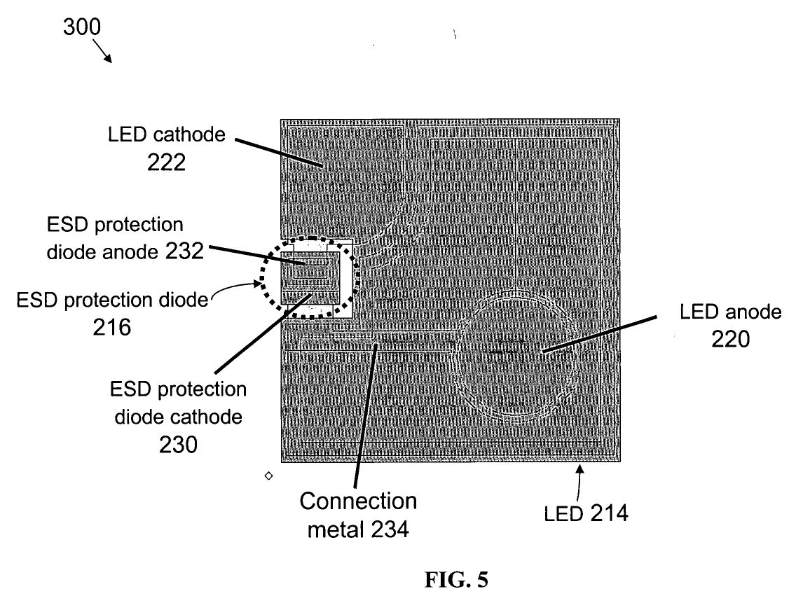

FIG. 5 shows another example of the monolithic integration of a light-emitting diode and an ESD protection diode according to the principles of the present invention. ESD-protection diode 216 in this example is relatively small in size compared with that of light-emitting diode 216. With this configuration, integrated device 300 can minimize the increase in the operating voltage and the decrease in the light output. Due to the small size of ESD-protection diode 216, the forward operating voltage and the light output can be almost the same as that of a corresponding single diode device (see Example 3).

In another embodiment, the integrated device of the invention includes multiple light-emitting devices that includes a light-emitting diode. The light-emitting diodes are formed from multiple p-n diode structures made from a p-n junction structure that is monolithically grown as described above.

Since individual light-emitting diodes perform light-emitting function while connected with each other or with one another, this serially-connected device provides light output substantially equal to that of a single light-emitting diode multiplied by the number of total diodes connected in series. The monolithic integration of the invention provides a simpler and more reliable solution than the use of the same number of discrete devices connected by a wire-bonding or bump-bonding known in the art. Because multiple light-emitting devices are integrated monolithically over a common insulating substrate prior to packaging, the total number of terminals connected in the package can be reduced. Thus, with the integrated device of the invention, the substantially same level of performance can be achieved from a single light-emitting device package as that of the same number of discrete packages.

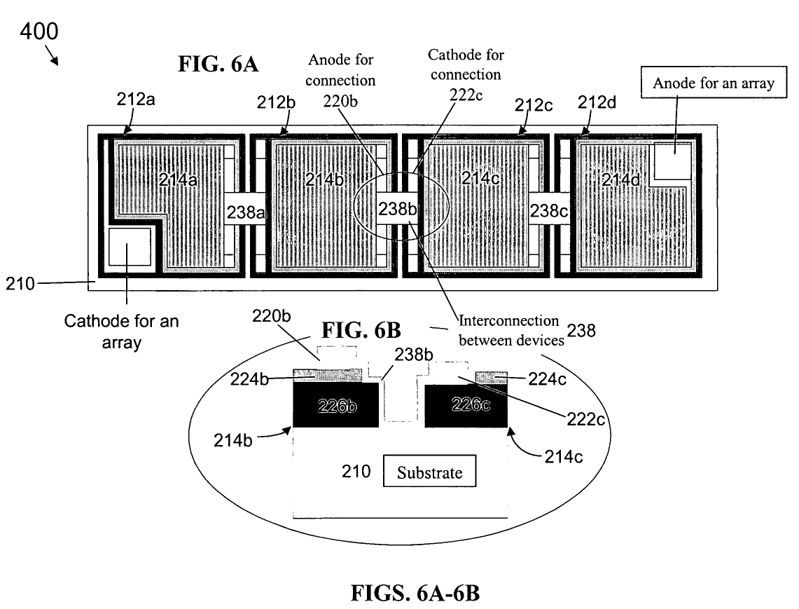

FIG. 6A shows a top view of integrated device 400 of the invention. Integrated device 400 includes four light-emitting devices 212a, 212b, 212c and 212d (collectively light-emitting devices 212), which are interconnected with one another in series. In this embodiment, light-emitting devices 212a-212d include light-emitting diodes 214a-214d, respectively. Light-emitting diodes 214a-214d are monolithically formed over a common single substrate 210. Prior to connecting light-emitting diodes 214a-214d in series, the diodes in the array are completely isolated electrically from one another by removal of conductive semiconductor layers. The interconnection between the adjacent light-emitting diodes is made during the device fabrication process, connecting the anode and cathode of adjacent diodes. For example, light-emitting diode 214a is connected with light-emitting diode 214b via connection metal 238a, light-emitting diode 214b is connected with light-emitting diode 214c via connection metal 238b, and light-emitting diode 214c is connected with light-emitting diode 214d via connection metal 238c. The interconnection made between the adjacent diodes generally requires smaller area for electrode than that for the external wire-bonding or bump-bonding.

FIG. 6B shows an enlarged cross-section of the circled area of FIG. 6A. As shown in FIG. 6B, light-emitting diodes 214b and 214c are interconnected through electrodes 220b and 222c of opposite polarities. The interconnection is made via connection metal 238b. In this example, p-type semiconductor layers 224b and 224c and semiconductor layers 226b and 226c form p-n diode structures for light-emitting diodes 214b and 214c, respectively. An insulating layer (not shown), such as insulating layer 136 shown in FIG. 2, can be further deposited between the p-n diode structure(s) of light-emitting diode(s) 214b and/or 214c and connection metal 238b.

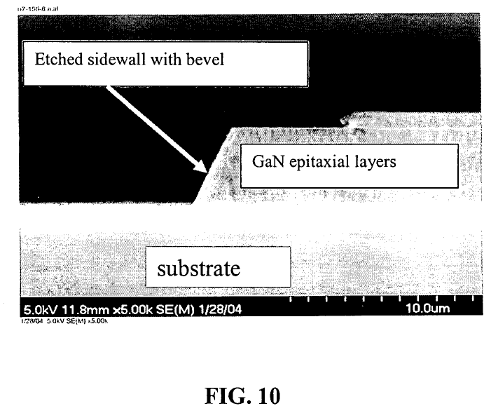

In yet another embodiment, the integrated device of the invention includes a plurality of light-emitting devices, where each of the light-emitting devices includes a light-emitting diode and an ESD-protection diode. The light-emitting and ESD-protection diodes are formed using a monolithic p-n junction structure, as discussed above. Electrodes of the light-emitting and ESD-protection diodes are interconnected with each other through electrodes of opposite polarities of the light-emitting and ESD-protection diodes of the light-emitting devices. Each of the light-emitting devices are also interconnected with each other or with one another through electrodes of opposite polarities of the light-emitting diode of the light-emitting devices. FIGS. 10A-10C show schematic views of an example of this embodiment.

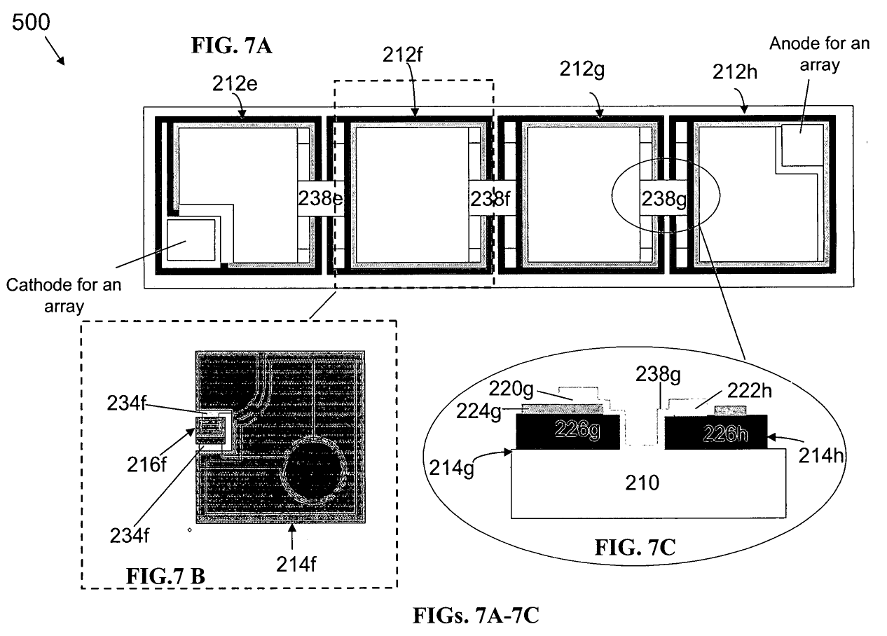

As shown in FIG. 7A, integrated device 500 includes four light-emitting devices 212f-212h that each include a light-emitting diode and an ESD-protection diode. FIG. 7B shows an enlarged view of the dotted square box of FIG. 7A, and illustrates interconnection between light-emitting diode 214f and ESD-protection diode 216f of light-emitting diode 212f via first connection metal 234f. FIG. 7C shows an enlarged cross-section of the circled area of FIG. 7A, illustrating interconnection between light-emitting diode 214g of light-emitting device 212g and light-emitting diode 214h of light-emitting device 212h via second connection metal 238g. Connection metal 238g connects p-side electrode 220g with n-side electrode 222h. P-side electrode 220g is in contact with p-type semiconductor layer 224g, and n-side electrode 222h is in contact with n-type semiconductor layer 226h. An insulating layer, such as insulating layer 136 shown in FIG. 2, can be further deposited under the first and second connection metals.

The electrodes of the light-emitting and/or ESD-protection diodes can be formed prior to depositing the connection metals. Alternatively, when the same materials are used for both the electrodes of diodes and connection metals, the electrodes and connection metals can be formed simultaneously. For example, in the embodiment of FIG. 4, electrodes 220, 222, 230 and 232 can be deposited simultaneously with connection metals 234. Also, in integrated device 400 of FIG. 6B, electrodes of light-emitting diodes 214a-214d can be deposited simultaneously with connection metals 238a-238c.

Any metals or combinations thereof, which are electrically conductive, can be used as the connection metals. Examples of the connection metals include gold, palladium and platinum.

P-side (anode) and n-side (cathode) electrodes can be formed on the p-type and n-type semiconductor layers, respectively, by methods known to those skilled in the art (see, for example, U.S. Pat. No. 6,734,091 and U.S. Patent Application Publication Nos. U.S. 2004/0000670A1 and U.S. 2004/0262621A1, and U.S. Patent Application filed on even date herewith under Attorney Docket Number 0717.2048-001, “Methods of Forming P-type Electrodes in Gallium Nitride-Based Light-Emitting Devices,” by Tchang-hun Oh, et. al., the entire teachings of which are incorporated herein by reference). The p-side and n-side electrodes are in electrical contact with the p-type and n-type semiconductor layers, respectively. Suitable materials for the electrodes of the p-n diodes in the invention can be found, for example, U.S. Pat. No. 6,734,091, U.S. 2004/0000670 A1 and U.S. 2004/0262621 A1.

For the integrated device of the invention, the insulating substrate is preferably sapphire. Because the sapphire substrate is electrically insulative, electrodes must be formed directly on the n-type and p-type semiconductor layers. In addition, since p-type semiconductor layers have only moderate conductitvity, a p-electrode typically is formed to cover substantially the entire surface of the p-type semiconductor layer, requiring the p-electrode substantially transparent. Thus, in a preferred embodiment, the light-emitting device of the invention includes a substantially transparent p-electrode, such as a nickel-oxide (see U.S. Pat. No. 6,734,091) or indium-oxide based p-electrode (see U.S. Patent Application filed on even date herewith under Attorney Docket Number 0717.2048-001).

In general, as most of light generated from semiconductor layers of light-emitting device is totally reflected at the interfaces that the semiconductor layers make either with the substrate or the encapsulating material, a significant portion of the generated light is guided and traveling laterally within the semiconductor layers. Since a considerable portion of this laterally traveling light eventually reaches the edge of the semiconductor layers exposed in the side of the device, the enhancement of light extraction can be achieved by introduction of more favorable surface conditions of the sidewall at the edge of the semiconductor layers.

One of the steps towards the embodiments of various types of monolithically-integrated light-emitting devices is the device isolation process, as all the p-n diodes have to be electrically isolated from each other before selective connections are made. With a carefully-designed isolation process, the light output from an individual light-emitting device can be increased, benefiting from enhanced light extraction through the etched sidewall(s) of the individual light-emitting device.

Accordingly, in any of the embodiments discussed above, any one of the light-emitting devices can have a light-emitting diode having at least one sidewall that is beveled.

In the isolation process, a device area is defined as an area including the p-n diode structures and any top surface area necessary for positioning the metal electrodes. Typically the device area is defined by a polygon with more than four sides. The area outside the device area is etched from the surface of the semiconductor layers of the p-n diode structures. The etching can proceed up to a complete removal of the semiconductor layers, exposing the substrate outside the device area as required for device isolation. The etching of the semiconductor layers, however, can proceed to any depth outside the device area for the enhancement of the light extraction from the etched sidewall, although a deeper etch is preferred in order to maximize the enhancement. The etching can be carried out in more than one side the polygon forming the device area to enhance the light extraction. The etching on all the sides of the polygon as required for device isolation is preferred to maximize the benefit.

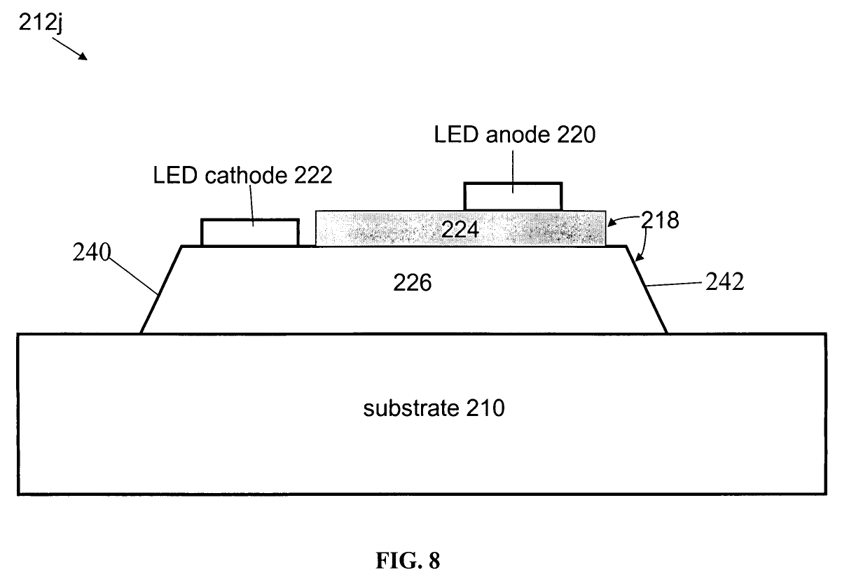

FIG. 8 shows light-emitting device 212j of an embodiment of the invention, which includes beveled sidewalls 240 and 242. P-n diode structure 218, including p-type semiconductor layer 224 and a stack of p- and n-type semiconductor layers 226, are formed on a substrate. Removal of the semiconductor layers can be achieved by the same techniques available for device isolation discussed above. Depending on the etching technique and etching conditions, the etched sidewall(s) has a bevel with different degrees of a slope. Preferably, the side wall is beveled to have a slope of about between 10 and about 50 degrees, more preferably about 30 degrees, with respect to a line normal to a major plane of the substrate. Optical simulation based on the ray-tracing methodology can be used to estimate the effects of different slopes in bevel. This methodology predicted about 15˜20% increase in the total light output from a light-emitting device with sidewalls having a 30 degrees slope with respect to a line normal to a major plane of the substrate compared to a light-emitting device with completely vertical sidewalls.

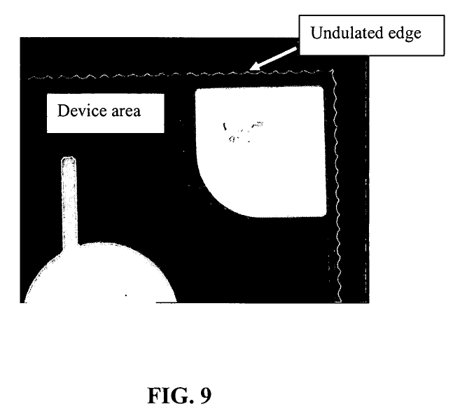

The etching process can be carried out by patterning an etch mask whose pattern is to be transferred to a top surface of the semiconductor layers. To enhance the light extraction further from the sidewall(s), the edge of the etched surface can be made undulated as shown in FIG. 9 or zigzagged by patterning the etch mask with an intentionally-designed photo-mask. Thus, in a preferred embodiment, the beveled sidewall is patterned, such as undulated or zigzagged.

Light-emitting device 212j of the invention can be used to enhance the light extraction where light emission is from either the bottom of the substrate or from the top surface of the semiconductor layers opposite the substrate. Depending upon the light-emitting sides, optionally, the etched sidewall(s) can be coated with a dielectric layer, such as silicon dioxide or silicon nitride, or a metal layer, such as a reflection layer, known in the art to increase light extraction.

A gallium nitride-based semiconductor material is a material having the formula InₓA_{y}Ga_{1-x-y}N, wherein x+y<1, 0≦x<1, and 0≦y<1. Gallium nitride-based semiconductor materials are usually grown by a vapor phase growth method such as metalorganic chemical vapor deposition (MOCVD or MOVPE, hydride chemical vapor deposition (HDCVD), or molecular beam epitaxy (MBE). Generally, a gallium nitride-based semiconductor material is an n-type material even when no n-type dopant is included in the material since nitrogen lattice vacancies are created during crystal growth. Thus, an n-type gallium nitride-based semiconductor material may not include an n-type dopant. However, an n-type gallium nitride-based semiconductor typically exhibits better conductivity when the material includes an n-type dopant. n-Type dopants for gallium nitride-based semiconductor materials include Group IV elements such as silicon, germanium and tin, and Group VI elements such as selenium, tellurium and sulfur.

A p-type gallium nitride-based semiconductor material is a gallium nitride-based semiconductor material that includes a p-type dopant. The p-type dopants (also called an acceptor) for gallium nitride-based semiconductor materials include Group II elements such as cadmium, zinc, beryllium, magnesium, calcium, strontium, and barium. Preferred p-type dopants are magnesium and zinc. Typically, during growth of the gallium nitride-based semiconductor material gaseous compounds containing hydrogen atoms are thermally decomposed to form the semiconductor material. The released hydrogen atoms, which are present mainly as protons, become trapped in the growing semiconductor material, and combine with p-type dopant, thereby inhibiting their acceptor function. To improve the conductivity of a p-type gallium nitride-based semiconductor material, the material may be placed in a high electric field, typically above 10,000 volts/cm for about 10 minutes or more. The protons trapped in the semiconductor material are drawn out of the material to the negative electrode, thereby activating the function of the p-type dopants (see, for example, U.S. Publication No. 2003/0199171, the entire teachings of which are incorporated herein by reference). Alternatively, the conductivity of the p-type gallium nitride-based semiconductor material can be improved by annealing the material at a temperature above 600° C. in a nitrogen environment for 10 minutes or more (see, for example, U.S. Pat. No. 5,306,662, the entire teachings of which are incorporated herein by reference).

As described above, a gallium nitride-based semiconductor structure includes an p-type gallium nitride-based semiconductor layer and n-type gallium nitride-based semiconductor layer. The p-type gallium nitride-based semiconductor layer is generally grown over the n-type gallium nitride-based semiconductor layer. The n-type and p-type semiconductor layers can be in direct contact with each other or, alternatively, an active region can be sandwiched between the n-type and p-type gallium nitride-based semiconductor layers. An active region can have a single quantum-well structure or a multiple quantum-well structure. An active region having a single quantum-well structure has a single layer (i.e., the well layer) formed of a gallium nitride-based semiconductor material having a lower band-gap than the n-type and p-type gallium nitride-based semiconductor layers sandwiching it. An active region having a multiple quantum-well structure includes multiple well layers alternately stacked with multiple layers that have a higher band-gap than the well layers (i.e., barrier layers). The outermost layer of the active region closest to the n-type gallium nitride-based semiconductor layer is a well layer and has a smaller band-gap than the n-type gallium nitride-based semiconductor layer. The outermost layer of the active region closest to the p-type gallium nitride-based semiconductor layer may be a well layer or a barrier layer and may have a band-gap that is larger or smaller than the p-type gallium nitride-based semiconductor layer. Typically, the thickness of a well layer in a quantum-well structure is about 70 Å or less, and the barrier layers are about 150 Å or less. Generally, the well layers and barrier layers in a quantum-well structure are not intentionally doped.

### EXEMPLIFICATION

### EXAMPLE 1

### Deposition of GaN-Based Semiconductor Layers on a Sapphire Substrate

Semiconductor layers were grown in a c-sapphire substrate by low-pressure MOCVD. The first deposited layer was a 20 nm-thick GaN nucleation layer, which was followed by a 4 μm-thick, silicon-doped (doping concentration of about 10¹⁹ cm⁻³) n-type GaN layer. The next layers were multiple quantum well active layers made of InₓGa₁₋ₓN/GaN (0<x<0.5) layers. The last layer was a 0.6 μm-thick Mg-doped p-type GaN top layer. The estimated concentration of the activated Mg dopants was approximately 3×10¹⁷ cm⁻³, as determined by the Hall measurement. After the MOCVD growth of the epitaxial layers, the device fabrication was carried out using conventional semiconductor processing techniques commonly used in industry.

### Example 2

### Device Fabrication: Monolithic Integration For ESD Protection

Using the semiconductor layers grown as described in Example 1, an integrated light-emitting device that includes a light-emitting diode and an ESD protection diode was monolithically fabricated. The integrated light-emitting device was fabricated following the schematic of the integration shown FIG. 4. The definition of two junction areas and the subsequent device isolation were achieved by ICP etching processes. Transparent contact layers based either on nickel-oxide (see U.S. Pat. No. 6,734,091) or on indium-oxide (see Attorney Docket Number 0717.2048-000) were deposited on top of the p-n junction areas to enhance the current spreading throughout the p-type GaN layers. In order not to short the diodes an insulating layer of silicon dioxide was deposited by plasma enhanced chemical vapor deposition (PECVD) on the whole surface. Openings were made in silicon dioxide layer by a chemical wet etching only in the areas of the top surface reserved for the electrodes. Gold-based electrodes (see U.S. 2004/000670A1) are deposited at the same time with a gold connection metal to complete the integration of two diodes.

Finished devices had a total area of 300×300 μm² with two p-n diodes, i.e., a light-emitting diode and an ESD-protection diode, which were integrated as shown in FIG. 4. For a comparison purpose, devices that contained only one light-emitting diode were also fabricated with the same total area. In order to make a fair comparison, all the devices were fabricated from a set of wafers that had a similar endurance to ESD.

Many testing methodologies known in the art can be used for testing tolerance of the integrated device of the invention against ESD. One of the most popular procedures is based on a human body model (HBM), simulating the impact of an ESD induced by human. In this example, the JEDEC HBM standard was used for the ESD test. During the test of the ESD tolerance against HBM, about 90% of the single diode devices failed at the ESD voltage level of 600V or below. On the other hand, 100% of the devices with two diodes that were tested showed endurance against HBM up to 6000V. The devices that included the nickel-oxide based contact layer and the devices that included the indium-tin-oxide based contact layer showed similar ESD protection against HBM. Hundred samples were tested for each of the integrated devices of the invention and control device. This result confirms a significant improvement in the ESD endurance as a result of the monolithic integration.

### Example 3

### Device Fabrication: Monolithic Integration For ESD Protection with a Relatively Small-Sized ESD-Protection Diode

FIG. 5 shows another example of the monolithic integration of a light-emitting diode and an ESD protection diode. The ESD protection diode in this example was made much smaller than that of Example 2 in order to minimize the increase in the operating voltage and the decrease in the light output. The fabrication process was the same as those of Example 2. The finished device size was 300×300 μm 2. During the test of the ESD tolerance in HBM, 100% of the devices with two diodes that were tested showed endurance against HBM up to 1000V. Hundred samples were tested for each device, i.e., the integrated device of the invention and control device. This result confirms an improvement in the ESD endurance as a result of the monolithic integration with a much smaller size protection diode. Due to the small size of the protection diode, the forward operating voltage and the light output were almost the same as those of the single-diode devices.

### Example 4

### Fabrication of a Light-emitting Device Having Beveled Sidewalls

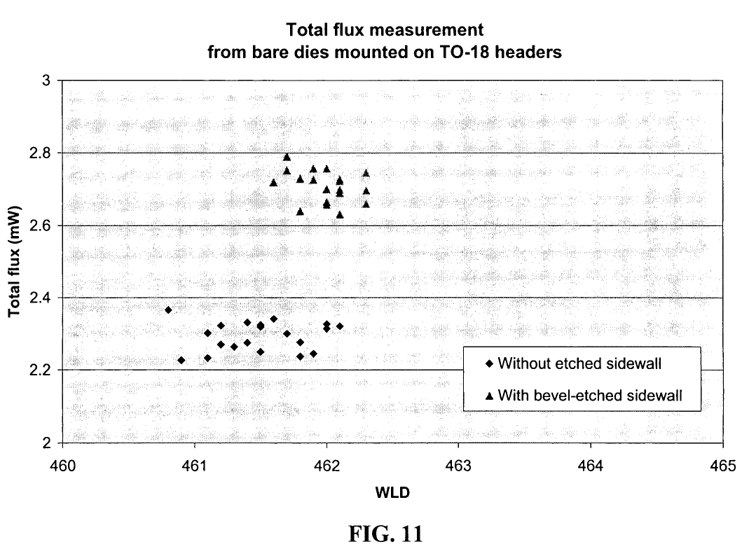

Light-emitting device whose structure was as shown in the schematic of FIG. 8 was fabricated. The beveled sidewalls with a slope of about 30 degrees with respect to a line normal to a major plane of the substrate were created on the sidewalls of the semiconductor epitaxial layers of the devices with specially tuned ICP etching conditions:
1) Gas flow: H₂ (50 sccm)+Cl (10 sccm)
2) ICP power: 2000 watts
3) RF power: 200 watts
4) Pressure: 5 mTorr
5) Etching time: 30 minutes.
   A cross-sectional scanning electron microscope image of the light-emitting device is shown in FIG. 10. The etching was carried out with an undulated mask pattern to produce a device as shown in FIG. 9. The improvement in the total light output from the devices with beveled sidewalls is shown in FIG. 11, which compares the light output in total flux from two groups of devices, one with the beveled sidewalls and the other without any beveled sidewalls. All the dies were picked from the same wafer and had the similar wavelength (WLD) for comparison. The comparison showed about 20% increase in light output from the devices with beveled sidewalls.

### EQUIVALENTS

While this invention has been particularly shown and described with references to preferred embodiments thereof, it will be understood by those skilled in the art that various changes in form and details may be made therein without departing from the scope of the invention encompassed by the appended claims.

1. An integrated device, comprising:
a) an insulating substrate; and
b) multiple p-n diodes of monolithic semiconductor materials over the insulating substrate.

2. The integrated device of claim 1, wherein the semiconductor materials are GaN-based semiconductor materials.

3. The integrated device of claim 2, wherein the p-n diodes include:
a) at least one light-emitting diode; and
b) at least one electro-static discharge protection diode,
where each light-emitting diode and each electro-static discharge protection diode are components of a light-emitting device.

4. The integrated device of claim 3, wherein each light-emitting diode and each electro-static discharge protection diode are interconnected through electrodes of opposite polarities of the light-emitting and electro-static discharge protection diodes.

5. The integrated device of claim 4, wherein the electrodes of opposite polarities of the light-emitting and electro-static discharge protection diodes are interconnected via a first connection metal.

6. The integrated device of claim 5, further including an insulating layer between the semiconductor materials of at least one of the light-emitting and electro-static discharge protection diodes and the first connection metal.

7. The integrated device of claim 6, wherein each light-emitting diode includes at least one sidewall that is beveled.

8. The integrated device of claim 7, wherein the beveled sidewall is patterned.

9. The integrated device of claim 8, wherein the beveled sidewall is undulated or zigzagged.

10. The integrated device of claim 7, wherein the sidewall is beveled to have a slope of between about 10 and about 50 degrees with respect to a line normal to a major plane of the substrate.

11. The integrated device of claim 7, wherein the beveled sidewall is coated with at least one layer of dielectric or metal.

12. The integrated device of claim 7, including a plurality of light-emitting devices.

13. The integrated device of claim 12, wherein the light-emitting devices are connected in series through electrodes of opposite polarities of the light-emitting diode component of the light-emitting devices.

14. The integrated device of claim 13, wherein the light-emitting devices are electrically interconnected via a second connection metal.

15. The integrated device of claim 14, further including an insulating layer between the semiconductor materials of at least one of the light-emitting diodes adjacent to each other and the second connection metal.

16. The integrated device of claim 2, wherein the p-n diodes include a plurality of light-emitting diodes, each light-emitting diode being a component of a light-emitting device.

17. The integrated device of claim 16, wherein the light-emitting devices are connected in series through electrodes of opposite polarities of the light-emitting diode component of the light-emitting devices.

18. The integrated device of claim 17, wherein the light-emitting devices are electrically interconnected via a second connection metal.

19. The integrated device of claim 18, further including an insulating layer between the semiconductor materials of at least one of the light-emitting diodes adjacent to each other and the second connection metal.

20. The integrated device of claim 19, wherein each of the light-emitting devices further includes an electro-static discharge protection diode, where the light emitting and electro-static discharge protection diodes are connected with each other through electrodes of opposite polarities of the light-emitting and electro-static discharge protection diodes.

21. The integrated device of claim 20, wherein the electrodes of opposite polarities of the light-emitting and electro-static discharge protection diodes are electrically interconnected via a first connection metal.

22. The integrated device of claim 21, further including an insulating layer between the semiconductor materials of at least one of the light-emitting and electro-static discharge protection diodes and the first connection metal.

23. A light-emitting device comprising:
a) a substrate; and
b) a light emitting diode over the substrate,
where at least one sidewall of the light-emitting diode is beveled.

24. The light-emitting device of claim 23, wherein the beveled sidewall is patterned.

25. The light-emitting device of claim 23, wherein the sidewall is beveled to have a slope of about 10-50 degrees with respect to a line normal to a major plane of the substrate.

26. The light-emitting device of claim 23, wherein the beveled sidewall is coated with at least one layer of dielectric or metal.

27. A method of producing an integrated device, comprising:
forming a monolithic p-n junction structure over an insulating substrate;
forming multiple electrically-isolated p-n diode structures from the monolithic p-n junction structure;
forming electrodes on the p-n diode structures to produce p-n diodes; and
interconnecting electrodes of opposite polarities of the p-n diodes.

28. The method of claim 27, wherein the semiconductor layers are GaN-based semiconductor layers.

29. The method of claim 28, wherein the p-n diodes include:
a) at least one light-emitting diode; and
b) at least one electro-static discharge protection diode,
where each light emitting diode and each electro-static discharge protection diode are components of a light-emitting device.

30. The method of claim 29, wherein the electrodes of opposite polarities of the light-emitting and electro-static discharge protection diodes are electrically interconnected via a first connection metal.

31. The method of claim 30, further including depositing an insulating layer between the p-n junction structure of at least one of the light emitting and electro-static discharge protection diodes and the first connection metal.

32. The method of claim 31, wherein the electrodes of the light-emitting and electro-static discharge protection diodes and the first connection metal are formed simultaneously.

33. The method of claim 31, further including forming a bevel on at least one sidewall of the light-emitting diode.

34. The method of claim 33, wherein the sidewall is beveled to have a slope of between about 10 and about 50 degrees with respect to a line normal to a major plane of the substrate.

35. The method of claim 34, further including patterning the beveled sidewall.

36. The method of claim 33, further including coating the beveled sidewall with at least one layer of dielectric or metal.

37. The method of claim 33, wherein the p-n diodes included a plurality of light-emitting diodes and a plurality of electro-static discharge protection diodes, each of the light-emitting diodes and each of the electro-static discharge protection diodes being components of a light-emitting device.

38. The method of claim 37, further including connecting the light-emitting devices in series through electrodes of opposite polarities of the light-emitting diode component of the light-emitting devices.

39. The method of claim 38, wherein the light-emitting devices are electrically interconnected via a second connection metal.

40. The method of claim 39, further including depositing an insulating layer between the p-n diode structure of at least one of the light-emitting diodes adjacent to each other and the second connection metal.

41. The method of claim 28, wherein the p-n diodes include a plurality of light-emitting diodes, each of the light emitting diodes is a component of a light-emitting device.

42. The method of claim 41, wherein the light-emitting devices are electrically connected in series through electrodes of opposite polarities of the light-emitting diode component of the light-emitting devices.

43. The method of claim 42, wherein the light-emitting devices are electrically interconnected via a second connection metal.

44. The method of claim 43, further including depositing an insulating layer between the p-n diode structure of at least one of the light-emitting diodes adjacent to each other and the second connection metal.

45. The method of claim 44, wherein the electrodes of the light-emitting diodes and the second connection metal are formed simultaneously.

46. The method of claim 44, wherein each of the light-emitting devices further includes an electro-static discharge protection diode, where each electro-static discharge protection diode is interconnected with the light-emitting diode component of the light-emitting devices through electrodes of opposite polarities of the light-emitting and electro-static discharge protection diodes.

47. The method of claim 46, wherein the light-emitting and electro-static discharge protection diodes are electrically interconnected via a first connection metal.

48. The method of claim 47, further including depositing an insulating layer between the p-n junction structure of at least one of the light emitting and electro-static discharge protection diodes and the first connection metal.

49. A method of producing a light-emitting device, comprising:
depositing multiple semiconductor layers over a substrate to produce a p-n junction structure;
forming a light-emitting diode structure using the p-n junction structure;
forming a bevel on at least one sidewall of the light-emitting diode structure; and
forming electrodes on the light-emitting diode structure to produce a light-emitting diode.

50. The method of claim 49, wherein the sidewall is beveled to have a slope of between about 10 and about 50 degrees with respect to a line normal to a major plane of the substrate.

51. The method of claim 49, further including coating the beveled sidewall with at least one layer of dielectric or metal.

52. The method of claim 49, further including patterning the beveled sidewall.

53. The method of claim 52, wherein the beveled sidewall is undulated or zigzagged.
